(19) United States
(12) Patent Application Publication
(10) Pub. No.: US 2011/0226327 A1
(43) Pub. Date: Sep. 22, 2011

(54) SOLAR CELL MODULE AND FABRICATING METHOD THEREOF

(75) Inventors: Chieh-Hsien Chan, Tainan (TW); Hsin-Chan Tseng, Tainan (TW)

(73) Assignee: AURIA SOLAR CO., LTD., Tainan (TW)

(21) Appl. No.: 13/151,071

(22) Filed: Jun. 1, 2011

(30) Foreign Application Priority Data
May 6, 2011 (TW) 100115942

(51) Int. Cl. H01L 31/0216; H01L 31/02; H01L 31/0232

(52) U.S. Cl. 136/256; 438/72; 257/E31.127

(57) ABSTRACT

A solar cell module includes a substrate, a first electrode layer, an active layer, a second electrode layer and a plurality of reflective layers. The first electrode layer is disposed on the substrate. The active layer is disposed on the first electrode layer. The second electrode layer is disposed on the active layer. The reflective layers are coated respectively on the second electrode layer.

### CROSS-REFERENCE TO RELATED APPLICATIONS

This non-provisional application claims priority under 35 U.S.C. §119(a) on Patent Application No. 100115942 filed in Taiwan, R.O.C. on May 6, 2011, the entire contents of which are hereby incorporated by reference.

### BACKGROUND OF THE INVENTION

1. Field of the Invention

The present invention relates to a solar cell module and a fabricating method thereof, and more particularly to a solar cell module, which provides higher photoelectric conversion efficiency and the fabricating thereof.

2. Description of the Prior Art

As the technology advances and development in the economy, human beings require more and more energy for their modern development. The naturally found crude petroleum, natural gas and coal, upon which, human beings rely heavily are gradually run out or in shortage as days gone by. So that the development and utilization of renewable energy that cause no environmental pollution have drawn the great attention for the human beings. As far as renewable energy is concerned, a solar cell has the features of ever-lasting energy, providing no environmental pollution and its energy consumption does not drain out the natural resources. Therefore, as we are facing energy shortage and environmental pollution, we have to find a way how to effectively utilize the solar energy is the main focus of the present day problem.

During fabrication of a conventional solar cell, a first electrode layer, a photovoltaic conversion layer and a second electrode layer are sequentially blanket-stacked on a substrate. While the photovoltaic conversion layer converts the sunlight into solar energy, the electrode layers permits flow of the current from one to the other. In order to enhance utilization of sunlight, a reflective layer is generally provided within the solar cell such that the light beam or sunlight passing through the photovoltaic conversion layer is reflected back into the photovoltaic conversion layer, thereby utilizing or absorbing the light beam once again.

Generally speaking, the reflective layer is applied on the back side of the solar cell in order to guide the sunlight beam reflected into the back photovoltaic conversion layer. However, due to restriction in the thickness of the coating process, the reflective layer usually has a relatively small thickness, thereby permitting the sunlight to pass therethrough and hence decreasing and lowering the reflective rate of the reflective layer.

Due to the above-mentioned facts, the inventor of the present invention feels that a new solar cell should be developed, in which the thickness of the reflective layer must be increased in order to raise the reflective rate of the reflective layer, thereby enhancing the photovoltaic conversion efficiency thereof.

### SUMMARY OF THE INVENTION

Therefore, due to restriction in the thickness and coating of the prior art reflective layer in the conventional solar cell module, the prior art reflective layer has a relatively small thickness so that the light beam can easily penetrate therethrough, which, in turn, decreases the reflectivity rate and lowers the utilization of the light beam within the prior solar cell module.

In order to solve the aforesaid problems, the main object of the present invention is to provide a fabricating method and solar cell module, in which, a first electrode layer is disposed on a substrate. Then, an active layer is disposed on the first electrode layer. Afterward, a second electrode layer is disposed on the active layer. Finally, a plurality of reflective layers are coated on the second electrode layer.

The solar cell module of the present invention accordingly includes a substrate, a first electrode layer, an active layer, a second electrode layer and a plurality of reflective layers. The first electrode layer is disposed on the substrate. The active layer is disposed on the first electrode layer. The second electrode layer is disposed on the active layer. The reflective layers are coated respectively on the second electrode layer.

Preferably, the substrate is transparent. The material for forming the first and second electrode layers includes TCO (transparent conductive oxide). The structure of the active layer may be the blanket-stacked structure or multi-contact face structure, wherein, the blanket-stacked structure may include a P-type semiconductor layer, an intrinsic layer and an N-type semiconductor layer (i.e., P-I-N stacked form) or a P-type semiconductor layer and an N-type semiconductor layer (i.e., p-n stacked form). Alternately, the active layer is a multiple blanket-stacked structure, for example, P-I-N/P-I-N stacked formation. The multiple blanket-stacked structure is composed of amorphous silicon, microcrystalline silicon, single crystalline silicon and polycrystalline silicon or a combination these elements. The multi-contact face structure is different from the multiple blanket-stacked structures, and is composed of compounds from Group IIIA-VA elements, Group IIA-VIA elements or is composed of multiple chemical compounds.

The method for fabricating the solar cell module in accordance with the present invention includes the steps of firstly disposing a first electrode layer over a substrate; secondly disposing an active layer over the first electrode layer; after which, disposing the second electrode layer over the active layer; and finally coating a plurality of reflective layers over the second electrode layer.

In one embodiment, the coating of the reflective layers is conducted by means of screen printing, spin coating, spray coating, scraper coating and slit coating.

In one embodiment, the aforesaid reflective layers are coated by the same coating process.

In one embodiment, the aforesaid reflective layers have a total thickness of 49 millimeter.

Preferably, white paints serve the material for formation of the aforesaid reflective layers.

In another embodiment, a roughening medium is formed between an adjacent pair of the aforesaid reflective layers.

As explained above, when compared to the prior art solar cell module, the fabricating method and solar cell module of the present invention is coated with a plurality of reflective layers over the second electrode layer, thereby increasing the total thickness of the reflective layers such that the reflectivity rate of the reflective layers is consequently increased, which, in turn, results in enhancement in the photovoltaic conversion efficiency of the solar cell module of the present invention.

In addition, due to multiple coating of the reflective layers and due to the presence of the roughening medium between an adjacent pair of the reflective layers, the reflectivity rate is further increased.

### BRIEF DESCRIPTION OF THE DRAWINGS

Other features and advantages of this invention will become more apparent in the following detailed description of the preferred embodiments of this invention, with reference to the accompanying drawings, in which:

FIG. 1 shows a cross-sectional view of the first embodiment of a solar cell module of the present invention;

FIG. 2 shows a step in the method for fabricating a solar cell module in accordance with the present invention;

FIG. 3 shows another step in the method for fabricating a solar cell module in accordance with the present invention; and

FIG. 4 shows a cross-sectional view of the second embodiment of the solar cell module of the present invention.

### DETAILED DESCRIPTION OF THE PREFERRED EMBODIMENTS

The fabricating method and solar cell module provided according to the present invention is widely applied in several types of solar cell assemblies in order to enhance the reflectivity of the reflective beam, thereby upgrading the photovoltaic conversion efficiency. Of course, due to different type of assembling the solar cell modules and fabrication methods thereof, a few embodiments are illustrated in the following paragraphs.

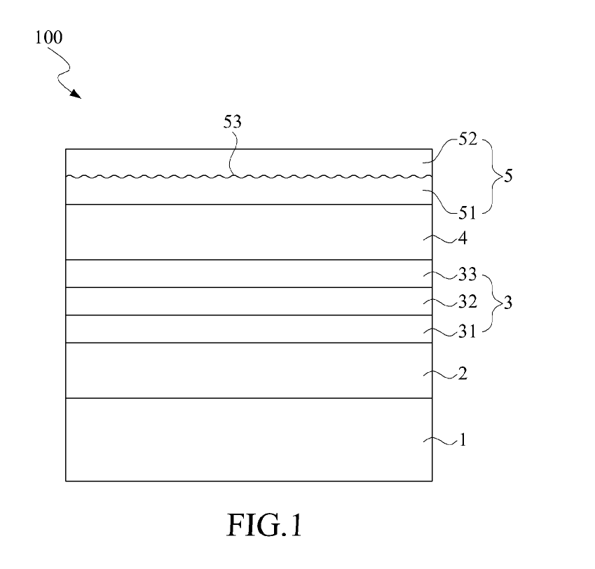

FIG. 1 shows a cross-sectional view of the first embodiment of a solar cell module of the present invention. As the solar cell module 100 accordingly includes a substrate 1, a transparent first electrode layer 2, an active layer 3, a transparent second electrode layer 4 and a plurality of reflective layers 5.

The transparent first electrode layer 2 is disposed on the substrate 1. The substrate 1 in fact is transparent and is made of glass or transparent resin. The stated transparent resin can be PET (polyethylene terephthalate), PEN (polyethylene naphthalate), PC (polycarbonate), PES (polyethersulfone) or PI (polyimide). However, the materials should not be limited only to those mentioned above. The materials for forming the first electrode layer 2 include TCO (transparent conductive oxide), which can be ITO (indium tin oxide), AZO (Al doped ZnO), or IZO (indium zinc oxide). However, the materials should not be limited only to those mentioned above.

The active layer 3 is disposed on the transparent first electrode layer 2, and is composed of a P-type semiconductor layer 31, an intrinsic layer 32 and a N-type semiconductor layer 33. The P-type semiconductor layer 31 is disposed on the transparent first electrode layer 2. The intrinsic layer 32 is disposed on the P-type semiconductor layer 31 while the N-type semiconductor layer 33 is disposed on the intrinsic layer 32. The material of forming the P-type semiconductor layer 31 consists of at least amorphous silicon, microcrystalline silicon, single crystalline silicon and polycrystalline silicon or a combination these elements. The doping materials for the P-type semiconductor layer 31 are selected from Group IIIA elements of the Periodic Table. The Group IIIA includes Baron (B), Aluminum (AL), gallium (Ga), Indium (In) or Thallium (Tl). The material of forming the intrinsic layer 32 consists of at least amorphous silicon and microcrystalline silicon or amorphous silicon and microcrystalline silicon, or a combination these elements. The material of forming the N-type semiconductor layer 33 consists of at least amorphous silicon, microcrystalline silicon or amorphous silicon and microcrystalline silicon, or a combination these elements. The doping materials for the N-type semiconductor layer 33 are selected Group VA elements of the Periodic Table. The Group VA consists of phosphorous (P), Arsenic (As), Antimony (Sb) and Bismuth (Bi).

The second electrode layer 4 is disposed on the N-type semiconductor layer 33 of the active layer 3. The material for forming the second electrode layer 4 is transparent conductive oxides, which consists of Indium tin oxides, Aluminum Zinc oxides, Indium Zinc oxides or other transparent conductive materials.

The reflective layers 5 includes a first reflective layer 51 coated over the second electrode layer 4 and a second reflective layer 52 coated over the first reflective layer 51, wherein a roughening medium 53 is formed between an adjacent pair of the first and second reflective layers 51, 52. In this embodiment, the reflective layers 5 have a total thickness of 49 millimeter or above. Preferably, the white paint serves as the material for forming the reflective layers 5, since white paint is constituted by water-based epoxy resin and pigments or dyes. The pigments may consist of Titanium dioxide.

As described above, we can draw a conclusion that t when the light beam enters the solar cell module 100 via the substrate 1, the light beam sequentially penetrates through the substrate 1, the transparent first electrode layer 2, the active layer 3 and the transparent second electrode layer 4, wherein a portion of the light beam not absorbed by the active layer 3 is reflected by the first reflective layer 51. At the same time, other portion of the light beam not reflected by the first reflective layer 51 penetrates continuously into the second reflective layer 52, which reflects said other portion of the light beam back into the active layer 3. Since the roughening medium 53 is formed between the adjacent pair of the first and second reflective layers 51, 52, the light beam is thus reflected or refracted by the roughening medium 53 continuously, thereby enhancing the reflection rate of the reflective layers 5.

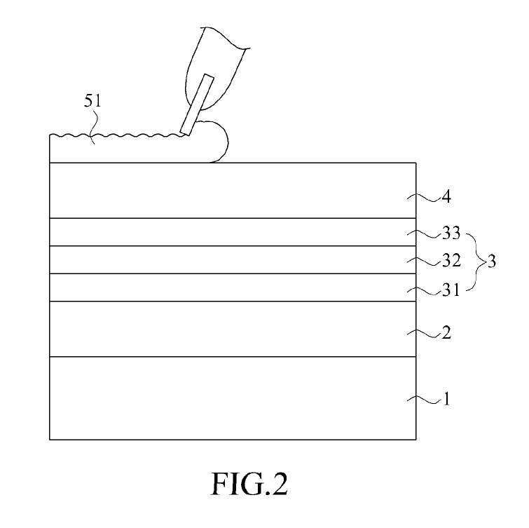

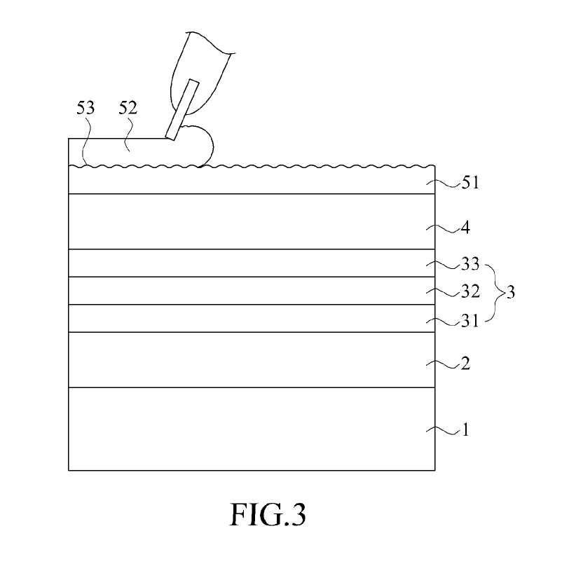

Referring to FIGS. 2 and 3, wherein FIG. 2 shows a step in the method for fabricating the solar cell module in accordance with the present invention while FIG. 3 shows another step in the method for fabricating the solar cell module in accordance with the present invention. As illustrated, the method for fabricating the solar cell module 100 in accordance with the present invention includes the steps of firstly disposing the first electrode layer 2 over the substrate 1; secondly disposing the second electrode layer 4 over the active layer 3; after which, coating the first reflective layer 51 over the second electrode layer 4; and finally coating the second reflective layer 52 over the first reflective layer 51.

In this embodiment, the first electrode layer 2 and the second electrode layer 4 are formed by one of, for example, chemical vapor deposition (CVD), evaporation or sputtering process. Preferably, the first electrode layer 2 and the second electrode layer 4 are formed by CVD.

In this embodiment, the active layer 3 is formed by chemical vapor deposition (CVD). In addition, the active layer 3 may the blanket-stacked structure or multi-contact face structure, wherein, the blanket-stacked structure may include a P-type semiconductor layer, an intrinsic layer and an N-type semiconductor layer (i.e., P-I-N stacked form) or P-type semiconductor layer and an N-type semiconductor layer (i.e., p-n stacked form). Alternately, the active layer 3 is multiple blanket-stacked structures, for example, P-I-N/P-I-N stacked formation. The multiple blanket-stacked structure is composed of amorphous silicon, microcrystalline silicon, single crystalline silicon and polycrystalline silicon or a combination these elements. The multi-contact face structure is different from the multiple blanket-stacked structures, and is composed of compounds from Group IIIA-VA elements, Group IIA-VIA elements or is composed of multiple chemical compounds.

In the other embodiment, the coating of the reflective layers 5 is conducted by means of screen printing, spin coating, spray coating, scraper coating and slit coating. Preferably, white paints serve the material for formation of the first and second reflective layers 51, 52. The screen printing is used for coating the first and second reflective layers 51, 52. In addition, since the first and second reflective layers 51, 52 respectively have relatively small thickness, the first reflective layer 51 dries up immediately after the first screen printing operation so that there is no need to wait for conducting the second screen printing operation. Since the first and second reflective layers 51, 52 are not fabricated integrally, a roughening medium is naturally formed between the first and second reflective layers 51, 52 such that the roughening medium enhances the amount of reflectivity therewithin. Preferably, the reflective layers 5 have a total thickness of 49 millimeter.

In other embodiments, the first and second reflective layers 51, 52 are fabricated from different materials, wherein the first reflective layer 51 is composed of white paint whereas the second reflective layer 52 is composed of colloidal sol with white pigment and the first and second reflective layers 51, 52 are coated in different coating process. For instance, the first reflective layer 51 is coated by means of screen printing operation while the second reflective layer 52 is coated by means of spin coating operation. In addition, in case the second reflective layer 52 is composed of colloidal sol, heating or drying up operation is required after the coating process in order to solidifying the second reflective layer 52.

The above-mentioned fabrication and coating process and the materials selected for the reflective layers are given as examples and the limitation should not be restricted only thereto. Several variations can be made within the scope of the present invention.

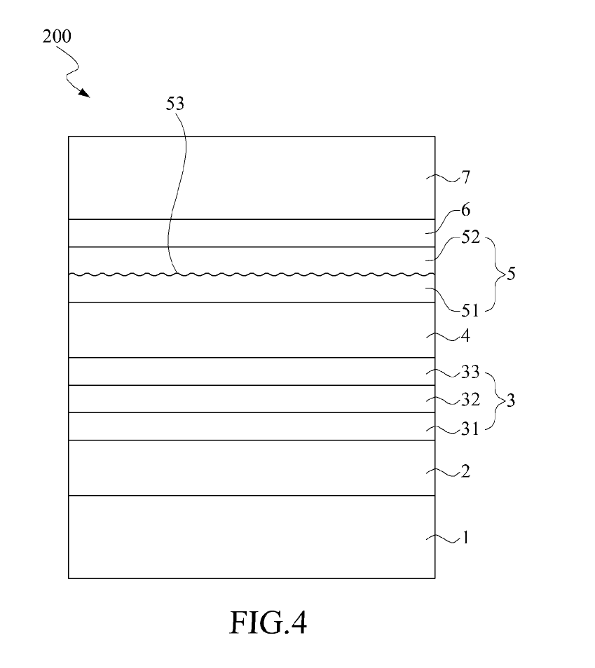

FIG. 4 shows a cross-sectional view of the second embodiment of the solar cell module of the present invention. As illustrated, the second embodiment has the structure similar to that of the first embodiment. The only difference resides in that the second embodiment further includes a transparent adhesive layer 6 and a back substrate 7. The transparent adhesive layer 6 is disposed on the second reflective layer 52, and is composed of PVB (Polyvinyl Butyral) or EVA (Ethylene Vinyl Acetate). However, the limitation should not be restricted only to those elements.

The back substrate 7 is disposed on the transparent adhesive layer 6, and is composed of glass or transparent resin. The transparent resin is selected from a group including, for instance, PET (polyethylene terephthalate), PEN (polyethylene naphthalate), PC (polycarbonate), PES (polyethersulfone) or PI (polyimide). However, the limitation should not be restricted only to those elements.

As described above, the second embodiment of the solar cell module 200 includes two substrates such that the light beam enters into the active layer 3 not only from the front substrate 1 but also from the back substrate 7.

In conclusion, when compared to that of the prior art solar cell module, the fabricating method and solar cell module of the present invention is coated with a plurality of reflective layers over the second electrode layer, thereby increasing the total thickness of the reflective layers such that the reflectivity rate of the reflective layers is consequently increased, which, in turn, results in enhancement in the photovoltaic conversion efficiency of the solar cell module of the present invention. In addition, due to presence of the roughening medium between an adjacent pair of the reflective layers, the reflectivity rate is further increased. Furthermore, the method of the present invention can be applied directly in the fabricating of the solar cell module without requiring additional apparatus so that the fabricating cost thereof is not increased but the reflectivity rate within the solar cell module can be increased. Hence the present invention provides high value market competition.

While the invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A method for fabricating a solar cell module comprising the steps of:
(a) disposing a first electrode layer on a substrate;
(b) disposing an active layer on said first electrode layer;
(c) disposing a second electrode layer on said active layer; and
(d) coating a plurality of reflective layers on said second electrode layer.

2. The solar cell module fabricating method according to claim 1, wherein the reflective layers have a total thickness of 49 millimeter.

3. The solar cell module fabricating method according to claim 1, wherein the coating on the reflective layer is done from a group consisting of a screen printing, a spin coating, a spray coating, a scraper coating and a slit coating.

4. The solar cell module fabricating method according to claim 3, wherein the reflective layers are respectively coated by the same coating process.

5. The solar cell module fabricating method according to claim 1, wherein each of the reflective layers is made from the same material.

6. The solar cell module fabricating method according to claim 1, wherein white paint serves as the material for making the reflective layers respectively.

7. The solar cell module fabricating method according to claim 1, wherein a roughening medium is formed between an adjacent pair of the reflective layers.

8. The solar cell module comprising:
a substrate;
a first electrode layer disposed on said substrate;
an active layer disposed on said first electrode layer;
a second electrode layer on said active layer; and
a plurality of reflective layers coated respectively on said second electrode layer.

9. The solar cell module according to claim 8, wherein the reflective layers have a total thickness of 49 millimeter.

10. The solar cell module according to claim 8, wherein white paint serves as the material for making the reflective layers respectively.

11. The solar cell module fabricating method according to claim 8, wherein a roughening medium is formed between an adjacent pair of the reflective layers.
